(19) United States
(12) Patent Application Publication
(10) Pub. No.: US 2022/0380249 A1
(43) Pub. Date: Dec. 1, 2022

(54) QUANTUM DOT-DOPED GLASS

(71) Applicants: Nick F. Borrelli, Corning, NY (US); Anthony Carapella, Corning, NY (US); Ming Huang Huang, Corning, NY (US); Joseph F. Schroeder, Corning, NY (US); Haitao Zhang, Corning, NY (US); Bin Zhu, Corning, NY (US)

(72) Inventors: Nick F. Borrelli, Corning, NY (US); Anthony Carapella, Corning, NY (US); Ming Huang Huang, Corning, NY (US); Joseph F. Schroeder, Corning, NY (US); Haitao Zhang, Corning, NY (US); Bin Zhu, Corning, NY (US)

(21) Appl. No.: 17/333,475

(22) Filed: May 28, 2021

(51) Int. Cl. C03C 4/12; C23C 16/455; C23C 16/40; C23C 16/34; C23C 16/50; C23C 28/04; C03B 25/02; C03C 17/22; C03C 17/245; C03C 14/00; C03C 3/089; C09K 11/88

(52) U.S. Cl. CPC C03C 4/12; C23C 16/45525; C23C 16/403; C23C 16/402; C23C 16/345; C23C 16/50; C23C 28/04; C03B 25/02; C03C 17/225; C03C 17/245; C03C 14/006; C03C 3/089; C09K 11/883; B82Y 20/00

(57) ABSTRACT

The present disclosure relates to a quantum dot-doped glass and method of making the same. A quantum dot-doped glass includes glass including quantum dots in an internal structure of the glass. The quantum dots within the glass have a photoluminescence quantum yield of greater than or equal to 10%.

### BACKGROUND

Semiconductor nanocrvstals (quantum dots) have attracted intense research interests in the past few decades. The typical size of quantum dot is less than 10 nm and is smaller than the Bohr radius of its electron and hole. As a result of spatial confinement of electron/hole wave functions, the electronic structure and band gap of quantum dots are dependent on particle size. Quantum dots therefore exhibit unique size-dependent photophysical properties, such as wavelength-tunable absorption and emission. Other advantages of quantum dots in optical applications include highly efficient emissions, narrow and symmetric emission spectra, and photostability. Researchers have long envisioned the use of quantum dots in optoelectronic devices such as light-emitting diodes (LEDs), photovoltaics (PVs), lasers, sensors, and luminescent solar concentrators (LECs). Recently, quantum dots have been successfully commercialized in bioimaging and display technologies.

For applications, quantum dots should be placed inside a robust host to avoid air-degradation. Incorporating pre-synthesized quantum dots into bulk glass is difficult because the melted glass (typically melting at >300° C.) can easily destroy quantum dots. Although quantum dots embedded in glass have been synthesized via phase precipitation of semiconductors inside a glass host, the surface of quantum dots made by this method is not well passivated, which results in low emission efficiency (typically less than 2% quantum yield).

Quantum dots with good surface passivation are generally synthesized by the colloidal solution method. Colloidal quantum dots include a semiconductor core capped with a layer of organic surfactant ligands. The surfactant ligands provide “electronic” passivation of the terminate dangling bonds which would otherwise act as carrier traps to quench radiative emissions. The photoluminescence (PL) emission quantum yield (QY) of the best colloidal quantum dots can reach 90%+ in solutions and 30%+ in thin films. In applications, colloidal quantum dots have been incorporated into a variety of organic polymers or fluids. However, the lifetime of these organic materials is short, especially when exposed to strong optical beams.

### SUMMARY OF THE INVENTION

The present disclosure provides a quantum dot-doped glass, The quantum dot-doped glass includes quantum dots in pores in the glass. The quantum dots are sealed within the glass via one or more layers of optically transparent material. The quantum dots within the glass have a photoluminescence quantum yield of ≥10%.

The present disclosure provides a quantum dot-doped glass. The quantum dot-doped glass includes porous porous borosilicate glass including quantum dots dispersed in pores in a surface layer of the glass, the pores having a pore size of 2 nm to 20 nm. The quantum dots are sealed within the glass via one or more layers of optically transparent material including a layer including Al₂O₃, SiO₂, Si₃N₄, or a combination thereof; a PVD- or PECVD-deposited layer having a thickness of 100 nm to 1000 nm, or a combination thereof. The surface layer has a thickness of 5 microns to 1000 microns. The quantum dots within the glass have a photoluminescence quantum yield of ≥10%.

The present disclosure provides a method of forming the quantum dot-doped glass of the present disclosure. The method includes treating a glass with a solution including quantum dots to fmn the quantum dot-doped glass,

The present disclosure provides a method of forming a quantum dot-doped glass. The method includes treating a glass with a solution including quantum dots to place the quantum dots into pores in the glass. The method includes sealing the quantum dots within the glass via one or more layers of optically transparent material to form the quantum dot-doped glass. The quantum dots within the glass have a photoluminescence quantum yield of ≥0%.

The quantum dot-doped glass and method of making the same of the present disclosure have various advantages over other quantum dot-doped glass and methods of making the same. For example, the quantum dots of the quantum dot-doped glass of the present invention can have bright photoluminescence, such as a photoluminescence yield of equal to or greater than 10%, 20%, 30%, or 40% or more. Such photoluminescence yield is higher than that of other quantum dot-doped glass, such as more than 10 times higher. The quantum dots of the quantum dot-doped glass of the present invention can he sealed within the glass with an optically transparent Al₂O₃ or SiO₂ thin film, providing a robust host for the quantum dots. The internal structure of the glass used to form the quantum dot-doped glass of the present invention, and/or the surface of the quantum dots, can be modified to tune the optical properties of the quantum dots as desired.

### BRIEF DESCRIPTION OF THE FIGURES

The drawings illustrate generally, by way of example, but not by way of limitation, various aspects of the present invention.

FIG. 1 illustrates a schematic of a CdSe/CdS/ZnS core/shell QD with alkyl-carboxylate surfactant ligands on its surface.

FIGS. 2A-B illustrate TEM images of colloidal CdSe/ZnS core/shell QDs.

FIG. 3 illustrates SEM images of cross sections of QD-doped Vycor glass at various distances from the surface of the glass.

FIG. 4A illustrates photoluminescence spectra of CdSe/ZnS QDs on silica glass (I), in pristine Vycor glass (II) and in HF-cleaned Vycor glass (III).

FIG. 4B illustrates CdSe/ZnS QDs doped HF-cleaned Vycor glass under UV light (280 nm lamp) excitation.

### DETAILED DESCRIPTION OF TILE INVENTION

Reference will now be made in detail to certain embodiments of the disclosed subject matter. While the disclosed subject matter will be described in conjunction with the enumerated claims, it will be understood that the exemplified subject matter is not intended to limit the claims to the disclosed subject matter.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise.

In this document, the terms “a,” “an,” or “the” are used to include one or more than one unless the context clearly dictates otherwise. The term “or” is used to refer to a nonexclusive “or” unless otherwise indicated. The statement “at least one of A and B” or “at least one of A or B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section.

In the methods described herein, the acts can be carried out in any order without departing from the principles of the invention, except when a temporal or operational sequence is explicitly recited. Furthermore, specified acts can be carried out concurrently unless explicit claim language recites that they be carried out separately. For example, a claimed act of doing X and a claimed act of doing Y can be conducted simultaneously within a single operation, and the resulting process will fall within the literal scope of the claimed process.

The term “about” as used herein can allow for a degree of variability in a value or range, for example, within 10%, within 5%, or within 1% of a stated value or of a stated limit of a range, and includes the exact stated value or range.

The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%. The term “substantially free of” as used herein can mean having none or having a trivial amount of, such that the amount of material present does not affect the material properties of the composition including the material, such that about 0 wt % to about 5 wt % of the composition is the material, or about 0 wt % to about I wt %, or about 5 wt % or less, or less than, equal to, or greater than about 4.5 wt %, 4, 3.5, 3, 2.5, 2, 1.5, 1, 0.9, 0.8, 0.7, 0.6, 0.5, 0.4, 0.3, 0.2, 0.1, 0.01, or about 0.001 wt % or less, or about 0 wt %.

### Quantum Dot-Doped Glass

Various aspects of the present disclosure provide a quantum dot-doped glass. The quantum dot-doped glass includes glass that includes quantum dots in an internal structure of the glass. The quantum dots within the glass can have a photoluminescence quantum yield of ≥10%.

The quantum dots within the quantum dot-doped glass can have any suitable photoluminescence quantum yield, such as a photoluminescence quantum yield of ≥10%, or ≥20%, or ≥30%, or ≥40%, or ≥10% to ≤60%, or less than or equal to 100% and greater than or equal to 10%, 12, 14, 16, 18, 20, 22, 24, 26, 28, 30, 32, 34, 36, 38, 40, 42, 44, 46, 48, 50, 55, 60, 65, 70, 75, 80 85, 90, or 95%. The photoluminescence quantum yield can be measured in any suitable way. For example, the photoluminescence quantum yield can be measured using the method described in Adv. Mater. 1997, 9, 230-232, by placing the quantum dot-doped glass into an integrating sphere including an optical fiber connected to a spectrophotometer and a baffle preventing direct illuminated of the optical fiber by the sample, irradiating the quantum dot-doped glass, and measuring the photoluminescence therefrom using the spectrophotometer.

The quantum dots can be doped within the glass in any suitable distribution therein. The quantum dots within the glass can be free of aggregates of the quantum dots, the aggregates having a largest dimension of greater than 50 nm and/or that includes more than 10 quantum dots aggregated together.

The quantum dots can be uniformly or heterogeneously dispersed within the glass. The quantum dots can be dispersed throughout the glass, or dispersed within a certain portion of the glass. The quantum dots can be dispersed within pores that are within the glass, such as uniformly dispersed within pores in the glass.

The quantum dots can be doped (e.g., dispersed) in a surface layer of the glass. The surface layer of the glass can have any suitable thickness, such as a thickness of 1 micron to 2000 microns, or 5 microns to 1000 microns, or less than or equal to 2000 microns but greater than or equal to 1 micron, 2, 3, 4, 5, 6, 8, 10, 12, 14, 16, 18, 20, 25, 50, 75, 100, 150, 200, 250, 500 750, 1000, 1250, 1500, or 1750 microns. The quantum dots can have any suitable concentration profile within the surface layer. The quantum dots can have a uniform concentration throughout the surface layer. The quantum dots can have a gradient concentration within the surface layer (e.g., decreasing concentration with increasing distance away from the exterior surface of the glass).

The quantum dots can be doped into the glass such that washing of the quantum dot-doped glass with an organic solvent is not sufficient to wash the quantum dots out of the glass. For example, washing of the quantum dot-doped glass with toluene can be insufficient to wash the quantum dots out of the quantum dot-doped glass.

The quantum dots can form any suitable proportion of the quantum dot-doped glass. For example, the quantum dots can be 0.0001 wt % to 5 wt % of the quantum dot-doped glass, or 0.001 wt % to 1 wt % of the quantum dot-doped glass, or less than or equal to 5 wt % and greater than or equal to 0.0001 wt %, 0.0005, 0.001, 0.005, 0.01, 0.05, 0.1, 0.5, 1, 1.5, 2, 2.5, 3, 3.5, 4, or 4.5 wt % of the quantum dot-doped glass.

The quantum dots of the quantum dot-doped glass can be in pores in the glass. The pores can have a greater diameter than the quantum dots that are doped in the glass, The glass can include pores having any suitable pore size, such as a pore size of 1 nm to 50 nm, 2 nm to 20 nm, 4 nm to 10 nm, or less than or equal to 50 nm and greater than or equal to 1 nm, 2, 3, 4, 5, 6, 7, 8, 9, 10, 11, 12, 13, 14, 15, 16, 17, 18, 19, 20, 22, 24, 26, 28, 30, 32, 34, 36, 38, 40, 42, 44, 46, or 48 nm.

The glass can be any suitable type of glass, such as a type of porous glass. The glass can be a porous borosilicate glass. The borosilicate glass can include silica and boron trioxide. The borosilicate glass can further include sodium oxide, aluminum oxide, or a combination thereof. The borosilicate glass can be glass that has been treated to dissolved and/or extract a phase from the glass to form pores in the glass. in various examples, the borosilicate glass can include 50-98 wt % silica, or 60-98 wt %, or 80-98 wt %, or 90-98 wt %, or less than or equal to 98 wt % and greater than or equal to 50 wt %, 55, 60, 65, 70, 75, 80, 82, 84, 86, 88, 90, 91, 92, 93, 94, 95, 96, or 97 wt % silica. The borosilicate glass can include 1-50 wt % boron trioxide, or 1-40 wt %, or 1-20%, or 1-10%, or less than or equal to 50 wt % and greater than or equal to 1 wt %, 2, 3, 4, 5, 6, 7, 8, 9, 10, 12, 14, 16, 18, 20, 25, 30, 35, 40, or 45 wt %. The borosilicate glass can include 0.01-20 wt % aluminum oxide, sodium oxide, or a combination thereof, or 0.01-10 wt %, or 0.01-5 wt %, or equal to or less than 20 wt % and greater than or equal to 0.01 wt %, 0.05, 0.1, 0.2, 0.3, 0.4, 0.5, 0.6, 0.7, 0.8, 0.9, 1, 1.2, 1.4, 1.6, 1.8, 2, 3, 4, 5, 6, or 8 wt % aluminum oxide, sodium oxide, or a combination thereof.

The glass can be Vycor® glass, manufactured by Corning Inc. of Corning, N.Y. The glass can include an alkali-borosilicate glass that has been phase separated and has had the resulting alkali- and boric acid-rich phase dissolved in acid without subsequent melting to consolidate pores thereof. The glass can include about 96 wt % silica (e.g., 94-98 wt %, or 95-97 wt %) and about 2-4 wt % boron trioxide (e.g., 1-6 wt %, or 2-5 wt %). Generally, VYCOR® starts as an alkali borosilicate glass that is put through processing steps to transform the alkali borosilicate glass into a 96% silica structure. This 96% silica structure can be a porous body or a consolidated glass body. The VYCOR® product and a glass precursor are described in Corning Inc.'s U.S. Pat. No. 2,106,744 (the '744 Patent), which is hereby incorporated by reference in its entirety. As disclosed therein, glass compositions in a certain region of the ternary system R₂O/B₂O₃/SiO₂ will, on the proper heat treatment, separate into two phases. One of the phases is very rich in silica, whereas the other phase is very rich in alkali and boric oxide which is then acid dissolved or sol-gel extracted to form the porous glass.

The glass can have a porosity of about 1% to 40%, 10% to 40%, or 20% to 35%, or 25% to 30%, or less than or equal to 40 wt % and greater than or equal to 1%, 2, 4, 6, 8, 10, 12, 14, 16, 18, 20, 21, 22, 23, 24, 25, 26, 27, 28, 29, 30, 31, 32, 33, 34, 35, 36, or 38%. The glass can have a surface area of 100 m²/g to 400 m²/g, or 150 m²/g to 300 m²/g, or 175 m²/g to 250 m²/g, or less than or equal to 400 m²/g and greater than or equal to 100 m²/g, 120, 140, 160, 180, 200, 220, 240, 260, 280, 300, 320, 340, 360, or 380 m²/g. The glass can be formed using any suitable phase separation temperature, such as a phase separation temperature of 500° C. to 700° C., or 560° C. to 600° C., or less than or equal to 700° C. and greater than or equal to 500° C., 520, 540, 560, 580, 600, 620, 640, 660, or 680° C. The glass can be formed using any suitable acid-leaching time, such as a time of 3 days to 30 days, or less than or equal to 30 days and greater than or equal to 3 days, 4, 6, 8, 10, 12, 14, 16, 18, 20, 22, 24, 26, or 28 days.

The quantum dot-doped glass can be a modified glass, such as modified via one or more surface treatments prior to doping with the quantum dots. The glass can be hydrofluoric acid (HF)-modified. The HF-modification can include modification of the internal surface of the glass (e.g., the internal structure of pores of the glass that have access to the exterior of the glass) with HF having a concentration of 0.01 wt % to 10 wt % in water, 0.1 wt % to 1 wt %, or less than or equal to 10 wt % and greater than or equal to 0.01 wt %, 0.1, 1, 2, 3, 4, 5, 6, 7, 8, or 9 wt %. The HF-modification can be performed for any suitable duration, such as a duration of 1 h to 200 h, 12 h to 36 h, or less than or equal to 200 h but greater than or equal to 1 h, 2, 4, 6, 8, 10, 12, 14, 16, 18, 20, 22, 24, 36, 48, 72, 96, 100, 120, 140, 160, or 180 h.

Prior to doping, the glass can be modified with a Si—OH-reducing material that reduces surface Si—OH concentration of the glass. The Si—OH-reducing material can be any suitable material that reduces the concentration of Si—OH groups on the glass, such as Cl₂, F₂, NH₃, or a combination thereof. Prior to doping, the quantum dots can be modified with a surface-modifying material that reduces surface defects in the quantum dot, changes surface chemistry of the quantum dot, and/or increases quantum yield of the quantum dots doped in the glass. For example, the quantum dots can be modified prior to doping by a surface-modifying material including I₂, Br₂, Cl₂, an alkyl-carboxylate acid, an alkyl amine, an alkyl thiol, a metal alkyl-carboxylate complex, or a combination thereof.

The quantum dot-doped glass can be annealed after modification, such as annealed after an HF-modification and/or treatment with Si—OH-reducing material, The annealing can be any suitable annealing. The annealing can be performed in any suitable atmosphere; for example, the annealing can be performed in air, vacuum, or inert gas. The annealing can include annealing at 300° C. to 800° C., or 550° C. to 650° C.or less than or equal to 800° C. and greater than or equal to 300° C., 350, 400, 450, 500, 550, 600, 650, 700, or 750° C. The annealing can be performed for 1 min to 8 h, or 30 min to 2 h, or less than or equal to 8 h and greater than or equal to 1 min, 30 min, 1 h, 2, 3, 4, 5, 6, or 7 h.

The quantum dots can any suitable one or more type of quantum dots. The quantum dots can include a single type of quantum dots, or the quantum dots can include more than one type of quantum dot. The quantum dots can have a diameter (e.g., D50) of 1 nm to 50 nm, or 2 nm to 20 nm, or less than or equal to 50 nm and greater than or equal to 1 nm, 2, 3, 4, 5, 6, 7, 8, 9, 10, 11, 12, 13, 14, 15, 16, 17, 18, 19, 20, 22, 24, 26, 28, 30, 32, 34, 36, 38, 40, 42, 44, 46, or 48 nm, The quantum dot can include any suitable material, such as ZnO, ZnS, ZnSe, ZnTe, CdS, CdSe, CdTe, HgTe, HgSe, HgS, InAs, InP, InSb, Si, C, Ge, PbS, PbSe, PbTe, CuInS₂, CsPbCl₃, CsPbBr₃, CsPbI₃, alloys thereof, core/shell structures of any combination thereof, or combinations thereof. In various aspects, the quantum dots can include core-shell quantum dots (e.g., quantum dots including a core with a shell that encompasses the core), wherein the core and the shell can independently include ZnO, ZnS, ZnSe, ZnTe, CdS, CdSe, CdTe, HgTe, HgSe, HgS, InAs, InP, InSb, Si, C, Ge, PbS, PbSe, PbTe, CuInS₂, CsPbCl₃, CsPbBr₃, CsPbI₃, alloys thereof, or combinations thereof. The quantum dots can include CdSe. The quantum dots can include ZnS. The quantum dots can include CdSe ZnS core/shell quantum dots.

The quantum dots in the quantum clot-doped glass can be sealed within the glass (e.g., within pores in a surface layer of the glass). The quantum dots can be sealed within the glass via one or more layers of optically transparent material. The one or more layers of optically transparent material can have any suitable thickness, such as a thickness of 1 nm to 1500 nm, 5 nm to 1000 nm, 5 nm to 10 nm, or less than or equal to 1500 nm and greater than or equal to 1 nm, 2, 3, 4, 5, 6, 7, 8, 9, 10, 12, 14, 16, 18, 20, 22, 24, 26, 28, 30, 35, 40, 45, 50, 75, 100, 150, 200, 250, 500, 750, 1000, or 1250 nm. The one or more lavers of optically transparent material can include a layer including Al₂O₃, SiO₂, Si₃N₄, or a combination thereof. The one or more layers of optically transparent material can be deposited on the glass via any suitable technique, such as atomic layer deposition. The one or more lavers of optically transparent material can include a PVD- or PECVD-deposited layer having a thickness of 100 nm to 1000 nm. The one or more layers of optically transparent material can include a layer adjacent to the glass including Al₂O₃, SiO₂, Si₃N₄, or a combination thereof, that has a thickness of 5-10 nm, and a PVD- or PECVD-deposited layer thereon having a thickness of 100 nm to 1000 nm.

### Method of Forming a Quantum Dot-Doped Glass.

In various aspects the present invention provides a method of making the quantum dot-doped glass described herein. The method can be any suitable method that forms the quantum dot-doped glass described herein. For example, the method can include treating a glass (e.g., a porous glass) with a solution including quantum dots to form a quantum dot-doped glass. The quantum dot-doped glass includes glass that includes quantum dots in an internal structure of the glass. The quantum dots within the glass can have a photoluminescence quantum yield of ≥10%.

The treating of the glass with the solution including the quantum dots can be any suitable treating that dopes the quantum dots into an internal structure of the glass. The treating can include treating at any suitable temperature, such as 0° C. to 100° C., or 10° C. to 30° C., or room temperature, or less than or equal to 100° C. and greater than or equal to 0° C., 10, 15, 20, 25, 30, 35, 40, 50, 60, 70, 80, or 90° C. The treating can include soaking the glass in the solution. The soaking can be performed for any suitable duration, such as for a duration of 1 h to 1 week, or 24 h to 120 h, or less than or equal to 1 week and greater than or equal to 1 h, 2, 3, 4, 5, 6, 7, 8, 9, 10, 11, 12, 14, 16, 18 20, 22 h, 1 d, 1.5, 2, 2.5, 3, 4, 5, or 6 d. After the soaking, the method can include rinsing the treated glass with an organic solvent, such as a non-polar organic solvent, such as toluene.

The solution can include an organic solvent. The organic solvent can be any suitable organic solvent, such as a non-polar organic solvent. In various aspects, the solution includes toluene. The solution can have any suitable concentration of the quantum dots, such as a concentration of 0.01 mg/mL to 5 mg/mL, 0.1 mg/mL to 1 mg/mL, or less than or equal to 5 mg/mL and greater than or equal to 0.01 mg/mL, 0.05, 0.1, 0.5, 1, 1.5, 2, 2.5, 3, 3.5, 4, or 4.5 mg/mL.

The method can further include drying the treated glass. The drying can be any suitable drying that removes solvent from the treated glass. The drying can include drying under vacuum at room temperature.

The glass that is treated to form the quantum dot-doped glass can be any suitable type of glass, such as a type of porous glass. The glass can be a porous borosilicate glass. The glass can be Vycor® glass. The glass can include an alkali-borosilicate glass that has been phase separated and has had the resulting alkali- and boric acid-rich phase dissolved in acid without subsequent melting to consolidate pores thereof. The glass can include about 96 wt % silica (e.g., 94-98 wt %, or 95-97 wt %) and about 2-4 wt % boron trioxide (e.g., 1-6 wt %, or 2-5 wt %). The glass can have a porosity of about 1% to 40%, 10% to 40%, or 20% to 35%, or 25% to 30%, or less than or equal to 40 wt % and greater than or equal to 1%, 2, 4, 6, 8, 10, 12, 14, 16, 18, 20, 21, 22, 23, 24, 25, 26, 27, 28, 29, 30, 31, 32, 33, 34, 35, 36, or 38%. The glass can have a surface area of 100 m²/g to 400 m²/g, or 150 m²/g or 300 m²/g, or 175 m²/g to 250 m²/g, or less than or equal to 400 m²/g and greater than or equal to 100 m²/g, 120, 140, 160, 180, 200, 220, 240, 260, 280, 300, 320, 340, 360, or 380 m²/g. The glass can be formed using any suitable phase separation temperature, such as a phase separation temperature of 500° C. to 700° C., or 560° C. to 600° C., or less than or equal to 700° C. and greater than or equal to 500° C., 520, 540 560, 580, 600, 620, 640, 660, or 680° C. The glass can be formed using any suitable acid-leaching time, such as a time of 3 days to 30 days, or less than or equal to 30 days and greater than or equal to 3 days, 4, 6, 8, 10, 12, 14, 16, 18, 20, 22, 24, 26, or 28 days.

The glass that is treated to form the quantum dot-doped glass can be a modified glass, such as modified via one or more surface treatments prior to doping with the quantum dots. The glass can be hydrofluoric acid (HF)-modified. The HF-modification can include modification of the internal surface of the glass (e.g., the internal structure of pores of the glass that have access to the exterior of the glass) with HF having a concentration of 0.01 wt % to 10 wt % in water, 0.1 wt % to 1 wt %, or less than or equal to 10 wt % and greater than or equal to 0.01 wt %, 0.1, 1, 2, 3, 4, 5, 6, 7, 8, or 9 wt %. The HF-modification can be performed for any suitable duration, such as a duration of 1 h to 200 h, 12 h to 36 h, or less than or equal to 200 h but greater than or equal to 1 h, 2, 4, 6, 8, 10, 12, 14, 16, 18, 20, 22, 24, 36, 48, 72, 96, 100, 120, 140, 160, or 180 h.

Prior treating the glass with the solution including the quantum dots, the glass used to form the quantum dot-doped glass can be modified with a Si—OH-reducing material that reduces surface Si—OH concentration of the glass. The Si—OH-reducing material can be any suitable material that reduces the concentration of Si—OH groups on the glass, such as Cl₂, F₂, NH₃, or a combination thereof. Prior to treating the glass with the solution including the quantum dots, the quantum dots can be modified with a surface-modifying material that reduces surface defects in the quantum dot, changes surface chemistry of the quantum dot, and/or increases quantum yield of the quantum dots doped in the glass. For example, the quantum dots can be modified prior to doping by a surface-modifying material including I₂, Br₂, Cl₂, an alkyl-carboxylate acid, an alkyl amine, an alkyl thiol, a metal alkyl-carboxylate complex, or a combination thereof.

The glass used to form the quantum dot-doped glass can be annealed after modification, such as annealed after an HF-modification and/or treatment with Si—OH-reducing material and before performing the treatment of the glass with the solution including the quantum dots. The annealing can be any suitable annealing. The annealing can be performed in any suitable atmosphere; for example, the annealing can be performed in air, vacuum, or inert gas. The annealing can include annealing at 300° C. to 800° C., or 550° C. to 650° C., or less than or equal to 800° C. and greater than or equal to 300° C., 350, 400, 450, 500, 550, 600, 650, 700, or 750° C. The annealing can be performed for 1 min to 8 h, or 30 min to 2 h, or less than or equal to 8 h and greater than or equal to 1 min, 30 min, 1 h, 2, 3, 4, 5, 6, or 7 h.

The quantum dots in the solution can any suitable one or more type of quantum dots. The quantum dots can include a single type of quantum dots, or the quantum dots can include more than one type of quantum dot. The quantum dots can have a diameter (e.g., D50) of 1 nm to 50 nm, or 2 nm to 20 nm, or less than or equal to 50 nm and greater than or equal to 1 nm, 2, 3, 4, 5, 6, 7, 8, 9, 10, 11, 12, 13, 14, 15, 16, 17, 18, 19, 20, 22, 24, 26, 28, 30, 32, 34, 36, 38, 40, 42, 44, 46, or 48 nm. The quantum dot can include any suitable material, such as ZnO, ZnS, ZnSe, ZnTe, CdS, CdSe, CdTe, HgTe, HgSe, HgS, InAs, InP, InSb, Si, C, Ge, PbS, PbSe, PbTe, CuInS₂, CsPbCl₃, CsPbBr₃, CsPbI₃, alloys thereof, core/shell structures of any combination thereof, or combinations thereof. In various aspects, the quantum dots can include core-shell quantum dots (e.g., quantum dots including a core with a shell that encompasses the core), wherein the core and the shell can independently include ZnO, ZnS, ZnSe, ZnTe, CdS, CdSe, CdTe, HgTe, HgSe, HgS, InAs, InP, InSb, Si, C, Ge, PbS, PbSe, PbTe, CuInS₂, CsPbCl₃, CsPbBr₃, CsPbI₃, alloys thereof, or combinations thereof. The quantum dots can include CdSe. The quantum dots can include ZnS. The quantum dots can include CdSe/ZnS core/shell quantum dots.

The method can include sealing the quantum dots within the glass (e.g., within pores in a surface layer of the glass). The quantum dots can be sealed within the glass via one or more layers of optically transparent material. The one or more layers of optically transparent material can have any suitable thickness, such as a thickness of 1 nm to 1500 nm, 5 nm to 1000 nm, 5 nm to 10 nm, or less than or equal to 1500 nm and greater than or equal to 1 nm, 2, 3, 4, 5, 6, 7, 8, 9, 10, 12, 14, 16, 18, 20, 22, 24, 26, 28, 30, 35, 40, 45, 50, 75, 100, 150, 200, 250, 500, 750, 1000, or 1250 nm. The one or more layers of optically transparent material can include a layer including Al₂O₃, SiO₂, Si₃N₄, or a combination thereof. The method can include depositing the one or more layers of optically transparent material on the glass via any suitable technique, such as atomic layer deposition. The method can include depositing a PVD- or PECVD-deposited optically transparent layer having a thickness of 100 nm to 1000 nm. The method can include depositing a layer adjacent to the glass including Al₂O₃, SiO₂, Si₃N₄, or a combination thereof, that has a thickness of 5-10 nm, and PVD- or PECVD-depositing a layer thereon having a thickness of 100 nm to 1000 nm.

### EXAMPLES

Various aspects of the present invention can be better understood by reference to the following Examples which are offered by way of illustration. The present invention is not limited to the Examples given herein.

Porous Vycor glass is an ideal host material for nanoparticles in optical applications. It is transparent from visible to near infrared with an average pore size of less than 10 nm. The PL emission of CODs inside Vycor glass has not been studied. The Vycor glass used in this work has 5-10 nm pores in a 10 μm thick surface layer and the interior pore size is significantly smaller (<3 nm). The pore size and its distribution could be tuned during glass preparation by varying experimental conditions such as phase-separation temperature and acid-leaching time.

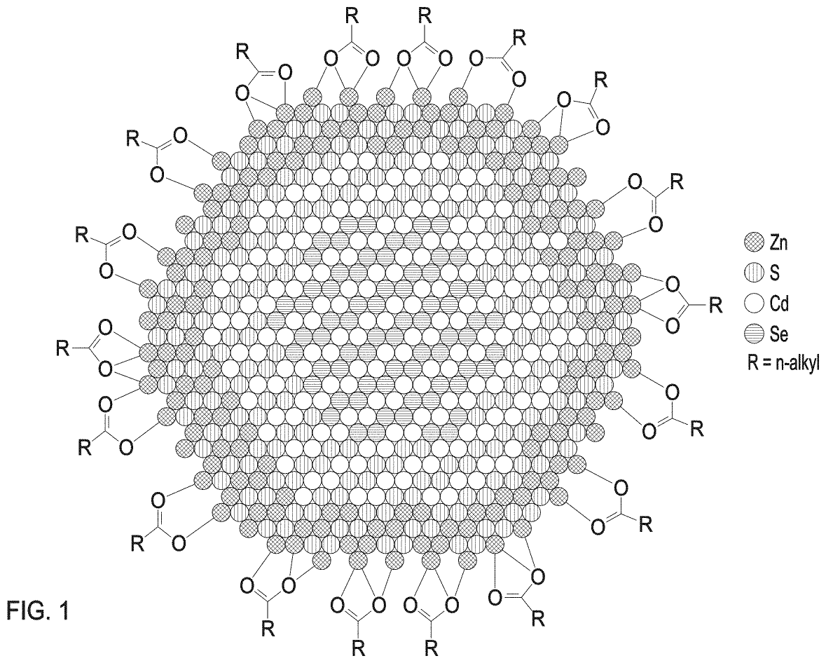

The surface of colloidal quantum dots can be passivated by a layer of organic surfactant ligands. One example is shown in FIG. 1, which illustrates a schematic of a CdSe/CdS/ZnS core/shell QD with alkyl-carboxylate surfactant ligands on its surface. When surfactants are anionic ligands such as carboxylate, the QD surface is metal-enriched. The carboxylate ligands bond to surface metal atoms to balance charge and passivate surface terminate bonds. The solubility of colloidal QDs in solvents also comes from surfactant ligands.

These surfactant ligands play an important role in synthesis to control quantum dots growth/shapes/size-distribution, and also enable the dispersion of quantum dots into organic solvents for solution-processing. Moreover, the “electronic” passivation of QD's surface dangling bonds by surfactant ligands is crucial for eliminating carrier traps and enhancing PL emissions. The most commonly used surfactant ligands are bulky alkyl molecules (C8-C18) with coordinating functional groups (such as —COOH, —NH₂, and the like), They bond to metal-enriched QDs surface to balance charges and provide steric protection. However, surfactant ligands and metal-surfactant complexes can be stripped off by coordinating chemicals (such as acid, H₂O, alcohol, and the like), which generates carrier traps and quenches PL emissions. This has been found to be a big challenge when incorporating QDs into matrix materials.

Vycor glass has a ˜200 m²/g internal surface which is covered by Si—OH terminal groups. H₂O is also present due to the hydrophilic surface. Both Si—OH groups and H₂O molecules can deteriorate QDs surface passivation by dissociating surfactant ligands. In this work, we used HF to modify the Vycor glass internal surface to improve the PL QY of loaded QDs.

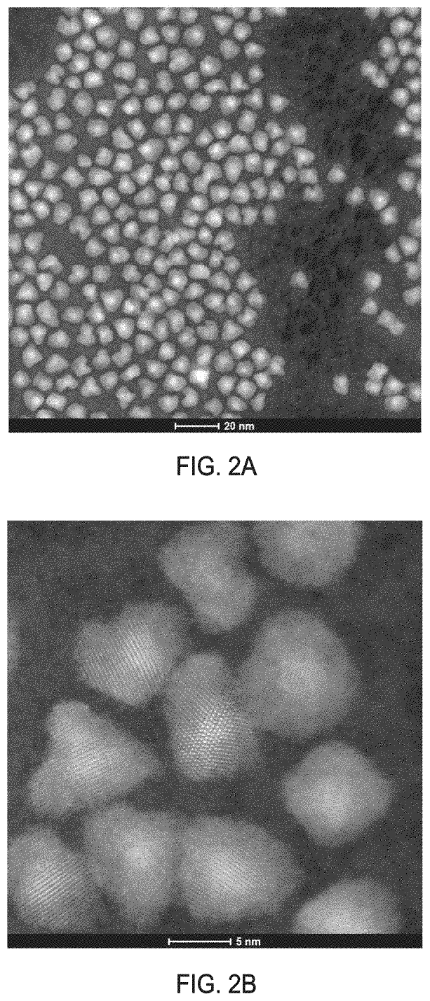

CdSe/ZnS core/shell QDs were used in our test. The QDs included a ˜2 nm diameter CdSe core and a ˜1.5 nm thick ZnS shell. FIGS. 2A-B illustrate TEM images of the colloidal CdSe/ZnS core/shell QDs, The QDs are the brighter spots in the TEM images. In such a core/shell structure, a secondary semiconductor (shell, with larger band gap) is grown on the “core” dot to improve surface passivation. But the “shell” is very thin (less than 2 nm thick) and cannot completely cover the core dot. Therefore, PL emission of core/shell QDs remains sensitive to the surface passivation.

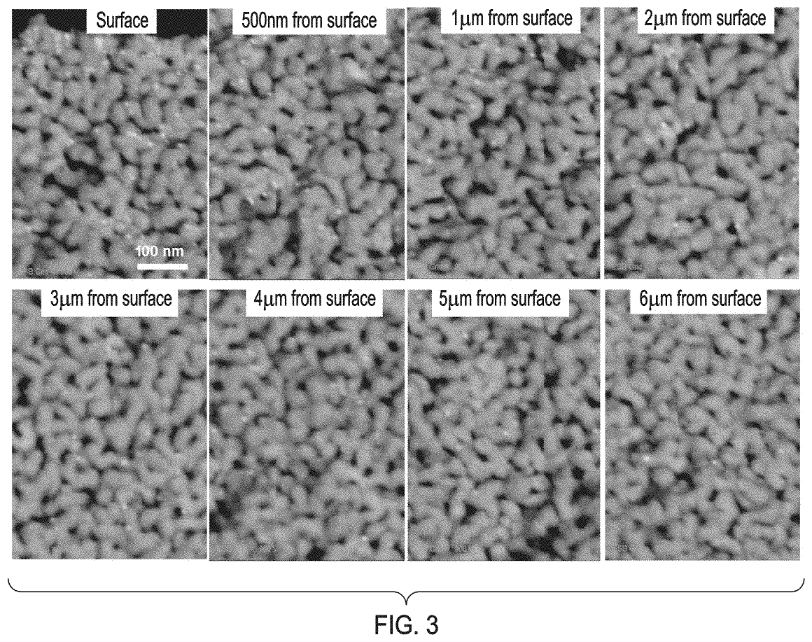

CdSe/ZnS QDs were impregnated into Vycor glass via a solution method. Before loading QDs, the Vycor glass (1 mm thick) was rinsed in a 0.25% HF solution for 24 hours and annealed in air at 600° C. for 1 hour. The glass was then soaked in a CdSe/ZnS QDs toluene solution (0.5 mg/mL) for 72 hours, followed by rinsing in pure toluene and drying under vacuum. FIG. 3 illustrates SEM images of cross sections of QD-doped Vycor glass at various distances from the surface of the glass. FIG. 3 shows the SEM image of the cross-section of QDs doped Vycor glass. The white dots in the SEM images are CdSe/ZnS QDs. QDs were dispersed inside Vycor glass within a ˜10 μm thick surface layer. The pores of the Vycor glass were larger than the QDs. The concentration of the QDs gradually decreased from glass surface to the interior. The loaded QDs could not be washed out by rinsing in toluene solvent, which indicated that the QDs had strong interactions with Vycor internal surface. The loading concentration of the QDs (over the whole glass) was estirnated to be about 0.02% (in weight; HF-treated Vycor glass).

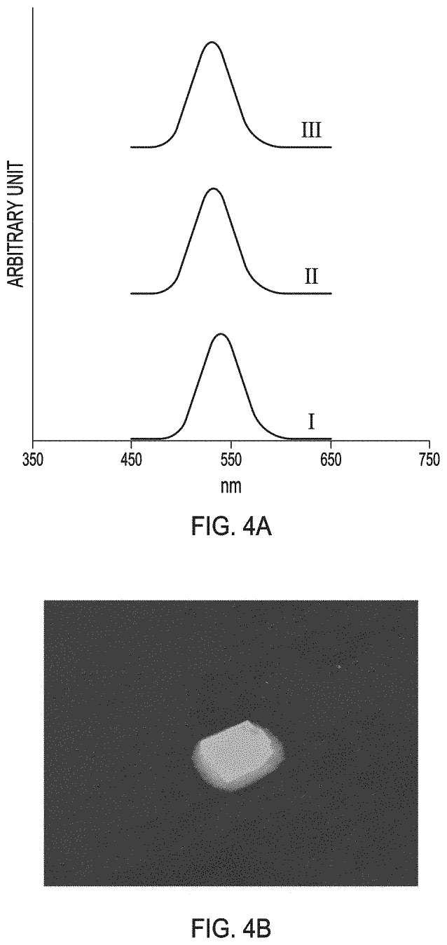

QDs inside Vycor glass showed the same characteristic photoluminescence (PL) emission wavelength, spectrum width) as pristine QDs, but the emission efficiency was sensitive to Vycor glass internal surface. FIG. 4A illustrates photoluminescence spectra of CdSe/ZnS QDs on silica glass (I), in pristine Vycor glass (II) and in HF-cleaned Vycor glass (III). QDs in I-III exhibit similar PL emission characteristics in emission wavelength and width, but very different emission efficiency. The intensity of spectra are normalized. FIG. 4B illustrates CdSe/ZnS QDs doped HF-cleaned Vycor glass under UV light (280 nm lamp) excitation. The PL quantum yield (QY) of QDs inside pristine Vycor glass is 7.5%. When QDs were loaded into HF-treated Vycor glass, the PL QY increased to 45%. The HF treatment must benefit QDs PL emission via modifying the internal surface of the Vycor glass. One hypothesis is that HF treatment removes some of surface Si—OH groups. As explained above, Si—OH groups can damage QDs surface passivation and reduce PL emission efficiency. HF treatment also improved loading efficiency of the QDs. In the same impregnation experiments, the amount of loaded QDs in BF-treated glass was 6 times as much as that in pristine Vycor glass, based on optical absorption. The HF treatment used in this work may slightly increase the pore size (although no noticeable size change was observed based on high resolution SEM images at 150K magnification). Another explanation for the improved loading efficiency could be the decrease of the surface Si—OH concentration after HF treatment; Si—OH groups could bond to the QD and halt its diffusion.

The PL QY of QDs in HF-treated Vycor glass (5%) was even higher than that of pristine QD thin films (32%). This is because QDs were well-dispersed inside Vycor glass (see FIG. 3) and had weaker inter-QD coupling than close-packed QD thin films. A possible explanation is that the inter-QD coupling can induce charge carrier diffusion between QDs and reduce PL quantum yield. The good dispersion of QDs inside Vycor glass provides opportunities to achieve PL emission efficiency comparable to that of colloidal QDs in organic solvents (≤90% QY), if the surfaces of Vycor glass or loaded QDs are modified to a better status. In addition to HF, Vycor glass surface can be modified by other chemicals such as Cl₂ and/or NH₃ to reduce Si—OH concentration. The surface chemistry of loaded QDs also can be modified to reduce defects density.

QDs inside Vycor glass maintained constant PL QY for more than 4 weeks when kept in air. The very small pore size (<10 nm) of Vycor glass may limit the diffusion of H₂O and O₂from air to degrade QDs. Moreover, QDs could be sealed inside Vycor glass by coating a layer of optically transparent Al₂O₃, or SiO₂ films on glass surface via atomic layer deposition (ALD). The ALD process was run under argon atmosphere and QDs were indeed permanently sealed inside Vycor glass under an air-free environment. After sealing by a 100 nm thick layer of Al₂O₃, QDs inside Vycor glass still showed bright emission with QY of 18%. The reduction of QY was due to the damage of the QDs in a surface layer (about 1 micrometer) by the ALD process. The PL QY can be improved by optimizing ALD process (temperature, chemicals, and the like), and by loading QDs into a thicker layer of Vycor glass.

The terms and expressions that have been employed are used as terms of description and not of limitation, and there is no intention in the use of such terms and expressions of excluding any equivalents of the features shown and described or portions thereof, but it is recognized that various modifications are possible within the scope of the embodiments of the present invention. Thus, it should be understood that although the present invention has been specifically disclosed by specific embodiments and optional features, modification and variation of the concepts herein disclosed may be resorted to by those of ordinary skill in the art, and that such modifications and variations are considered to be within the scope of embodiments of the present invention.

### Exemplary Aspects.

The following exemplary Aspects are provided, the numbering of which is not to be construed as designating levels of importance:

Aspect 1 provides a quantum dot-doped glass comprising:
glass comprising quantum dots in an internal structure of the glass, wherein the quantum dots within the glass have a photoluminescence quantum yield of ≥10%.

Aspect 2 provides the quantum dot-doped glass of Aspect 1, wherein the quantum dots have a photoluminescence quantum yield of ≥20%.

Aspect 3 provides the quantum dot-doped glass of any one of Aspects 1-2, wherein the quantum dots have a photoluminescence quantum yield of ≥40%.

Aspect 4 provides the quantum dot-doped glass of any one of Aspects 1-3, wherein the quantum dots are free of aggregates of the quantum dots within the glass that have a largest dimension greater than 50 nm or that comprise more than 10 quantum dots aggregated together.

Aspect 5 provides the quantum dot-doped glass of any one of Aspects 1-4, wherein the quantum dots are doped throughout the glass or within a surface layer of the glass.

Aspect 6 provides the quantum dot-doped glass of Aspect 5, wherein the surface layer has a thickness of 1 micron to 2000 microns.

Aspect 7 provides the quantum dot-doped glass of any one of Aspects 5-6, wherein the surface layer has a thickness of 5 microns to 1000 microns.

Aspect 8 provides the quantum dot-doped glass of any one of Aspects 5-7, wherein the quantum dots have a gradient concentration within the surface layer.

Aspect 9 provides the quantum dot-doped glass of any one of Aspects 5-8, wherein the quantum dots have a concentration within the surface layer decreases with increasing depth into the glass.

Aspect 10 provides the quantum dot-doped glass of any one of Aspects 5-9, wherein the quantum dots are dispersed within the surface layer.

Aspect 11 provides the quantum dot-doped glass of any one of Aspects 1-10, wherein washing of the quantum dot-doped glass with an organic solvent is not sufficient to wash the quantum dots out of the quantum dot-doped glass.

Aspect 12 provides the quantum dot-doped glass of any one of Aspects 1-11, wherein washing of the quantum dot-doped glass with toluene is not sufficient to wash the quantum dots out of the quantum dot-doped glass.

Aspect 13 provides the quantum dot-doped glass of any one of Aspects 1-12, wherein the quantum dots are 0.0001 wt % to 5 wt % of the quantum dot-doped glass.

Aspect 14 provides the quantum dot-doped glass of any one of Aspects 1-13, wherein the quantum dots are 0.001 wt % to 1 wt % of the quantum dot-doped glass,

Aspect 15 provides the quantum dot-doped glass of any one of Aspects 1-14, wherein the quantum dots are in pores in the glass.

Aspect 16 provides the quantum dot-doped glass of any one of Aspects 1-15, wherein the glass comprises pores having a greater diameter than the quantum dots doped in the glass.

Aspect 17 provides the quantum dot-doped glass of any one of Aspects 1-16, wherein the glass comprises a pore size of 1 nm to 50 nm.

Aspect 18 provides the quantum dot-doped glass of any one of Aspects 1-17, wherein the glass comprises a pore size of 2 nm to 20 nm.

Aspect 19 provides the quantum dot-doped glass of any one of Aspects 1-18, wherein the glass comprises porous borosilicate glass.

Aspect 20 provides the quantum dot-doped glass of any one of Aspects 1-19, wherein the glass comprises an aikali-borosilicate glass that has been phase separated and has had the resulting alkali- and boric acid-rich phase dissolved in acid without subsequent melting to consolidate pores thereof.

Aspect 21 provides the quantum dot-doped glass of Aspect 20 wherein the glass comprises about 96 wt % silica and about 2-4 wt % boron trioxide.

Aspect 22 provides the quantum dot-doped glass of any one of Aspects 1-21, wherein the glass is formed using a phase separation temperature of 560° C. to 600° C.

Aspect 23 provides the quantum dot-doped glass of any one of Aspects 1-22, wherein the glass is formed using an acid-leaching time of 3 days to 30 days.

Aspect 24 provides the quantum dot-doped glass of any one of Aspects 1-23, wherein the glass is HF-modified.

Aspect 25 provides the quantum dot-doped glass of Aspect 24, wherein the HF-modification comprises modification of the internal surface of the glass with HF having a concentration of 0.01 wt % to 10 wt % in water.

Aspect 26 provides the quantum dot-doped glass of any one of Aspects 24-25, wherein the HF-modification comprises modification of the internal surface of the glass with HF having a concentration of 0.1 wt % to 1 wt % in water.

Aspect 27 provides the quantum dot-doped glass of any one of Aspects 24-26, wherein the HF-modification comprises modification of the internal surface of the glass with HF for a duration of 1 h to 200 h.

Aspect 28 provides the quantum dot-doped glass of any one of Aspects 24-27, wherein the HF-modification comprises modification of the internal structure of the glass with HF for a duration of 12 h to 36 h.

Aspect 29 provides the quantum dot-doped glass of any one of Aspects 24-28, wherein the glass is annealed after HF-modification.

Aspect 30 provides the quantum dot-doped glass of Aspect 29, wherein the annealing comprises annealing in air.

Aspect 31 provides the quantum dot-doped glass of any one of Aspects 29-30, wherein the annealing comprises annealing at 300° C. to 800° C. for 1 min to 8 h.

Aspect 32 provides the quantum dot-doped glass of any one of Aspects 29-31, wherein the annealing comprises annealing at 550° C. to 650° C. for 30 min to 2 h.

Aspect 33 provides the quantum dot-doped glass of any one of Aspects 1-32, wherein the glass is modified with a Si—OH-reducing material that reduces surface Si—OH concentration of the glass.

Aspect 34 provides the quantum dot-doped glass of Aspect 33, wherein the Si—OH-reducing material comprises Cl₂, F₂, NH₃, or a combination thereof.

Aspect 35 provides the quantum dot-doped glass of any one of Aspects 1-34, wherein the quantum dot is modified with a surface-modifying material that reduces surface defects in the quantum dot, changes surface chemistry of the quantum dot, and/or increases quantum yield of the quantum dots doped in the glass.

Aspect 36 provides the quantum dot-doped glass of Aspect 35, wherein the surface-modifying material comprises I₂Br₂, Cl₂, an alkyl-carboxylate acid, an alkyl amine, an alkyl thiol, a metal al kyl-carboxylate complex, or a combination thereof.

Aspect 37 provides the quantum dot-doped glass of any one of Aspects 1-36, wherein the quantum dots comprise more than one type of quantum dot.

Aspect 38 provides the quantum dot-doped glass of any one of Aspects 1-37, wherein the quantum dots have a diameter of 1 nm to 50 nm.

Aspect 39 provides the quantum dot-doped glass of any one of Aspects 1-38, wherein the quantum dots have a diameter of 2 nm to 20 nm.

Aspect 40 provides the quantum dot-doped glass of any one of Aspects 1-39, wherein the quantum dots comprise ZnO, ZnS, ZnSe, ZnTe, CdS, CdSe, CdTe, HgTe, HgSe, HgS, InAs, InP, InSb, Si, C, Ge, PbS, PbSe, PbTe, CuInS₂, CsPhCl₃, CsPbBr₃, CsPbI₃, alloys thereof, core/shell structures of any combination thereof, or combinations thereof

Aspect 41 provides the quantum dot-doped glass of any one of Aspects 1-40, wherein the quantum dots comprise core/shell quantum dots, wherein the core and the shell independently comprise ZnO, ZnS, ZnSe, ZnTe, CdS, CdSe, CdTe, HgTe, HgSe, HgS, InAs, InP, InSb, Si, C, Ge, PbS, CuInS₂, CsPbCl₃, CsPbBr₃, CsPbI₃, alloys thereof, or combinations thereof.

Aspect 42 provides the quantum dot-doped glass of any one of Aspects 1-41, wherein the quantum dots comprise CdSe.

Aspect 43 provides the quantum dot-doped glass of any one of Aspects 1-42, wherein the quantum dots comprise ZnS.

Aspect 44 provides the quantum dot-doped glass of any one of Aspects 1-43, wherein the quantum dots comprise CdSe/ZnS core/shell quantum dots.

Aspect 45 provides the quantum dot-doped glass of any one of Aspects 1-44, wherein the quantum dots are sealed within the glass.

Aspect 46 provides the quantum dot-doped glass of any one of Aspects 1-45, wherein the quantum dots are sealed within the glass via one or more layers of optically transparent material.

Aspect 47 provides the quantum dot-doped glass of Aspect 46, wherein the one or more layers independently comprise a thickness of 1 nm to 1500 nm.

Aspect 48 provides the quantum dot-doped glass of any one of Aspects 46-47, wherein the one or more layers independently comprise a thickness of 5 nm to 1000 nm.

Aspect 49 provides the quantum dot-doped glass of any one of Aspects 46-48, wherein the one or more layers comprise a layer comprising Al₂O₃, SiO₂, Si₃N₄, or a combination thereof.

Aspect 50 provides the quantum dot-doped glass of any one of Aspects 49-49, wherein the layer comprising Al₂O₃, SiO₂, Si₃N₄, or a combination thereof, has a thickness of 5-10 nm.

Aspect 51 provides the quantum dot-doped glass of any one of Aspects 49-50, wherein the layer comprising Al₂O₃, SiO₂, Si₃N₄, or a combination thereof, is deposited on the glass via a technique comprising atomic layer deposition.

Aspect 52 provides the quantum dot-doped glass of any one of Aspects 46-51, wherein the one or more layers comprises a PVD- or PECVD-deposited layer having a thickness of 100 nm to 1000 nm.

Aspect 53 provides the quantum dot-doped glass of any one of Aspects 46-52, wherein the one or more layers comprises a layer adjacent to the glass comprising Al₂O₃, SiO₂, Si₃N₄, or a combination thereof, that has a thickness of 5-10 nm, and a PVD- or PECVD-deposited layer thereon having a thickness of 100 nm to 1000 nm.

Aspect 54 provides a quantum dot-doped glass comprising:
porous borosilicate glass comprising a pore size of 2 nm to 20 nm, the glass comprising quantum dots dispersed in pores in a surface layer of the glass, wherein the surface layer has a thickness of 5 microns to 1000 microns, and wherein the quantum dots within the glass have a photoluminescence quantum yield of ≥10%.

Aspect 55 provides a method of forming the quantum dot-doped glass of any one of Aspects 1-53, the method comprising:
treating a glass with a solution comprising quantum dots to form the quantum dot-doped glass of any one of Aspects 1-53.

Aspect 56 provides a method of forming a quantum dot-doped glass, the rrrethod comprising:
treating a glass with a solution comprising quantum dots to form the quantum dot-doped glass, wherein the quantum dot-doped glass comprises glass comprising quantum dots in an internal structure of the glass, wherein the quantum dots within the glass have a photoluminescence quantum yield of ≥10%.

Aspect 57 provides the method of Aspect 56, wherein the treating comprises treating at room temperature.

Aspect 58 provides the method of any one of Aspects 56-57, wherein the reatin comprises soaking the glass in the solution.

Aspect 59 provides the method of any one of Aspects 56-58, wherein the treating comprises soaking the glass in the solution for a duration of 1 h to 1 week.

Aspect 60 provides the method of any one of Aspects 56-59, wherein the treating comprises soaking the glass in the solution for a duration of 24 h to 120 h.

Aspect 61 provides the method of any one of Aspects 56-60, wherein the solution comprises an organic solvent.

Aspect 62 provides the method of any one of Aspects 56-61, wherein the solution comprises toluene.

Aspect 63 provides the method of any one of Aspects 56-62, wherein the solution has a concentration of the quantum dots of 0.01 mg/mL to 5 mg/mL.

Aspect 64 provides the method of any one of Aspects 56-63, wherein the solution has a concentration of the quantum dots of 0.1 mg/mL to 1 mg/mL

Aspect 65 provides the method of any one of Aspects 56-64, further comprising rinsing the treated glass with an organic solvent.

Aspect 66 provides the method of any one of Aspects 56-65, further comprising drying the treated glass.

Aspect 67 provides the method of Aspect 66, wherein the drying comprises drying under vacuum at room temperature.

Aspect 68 provides the method of any one of Aspects 56-67, wherein the glass comprises pores having a greater diameter than the quantum dots doped in the glass.

Aspect 69 provides the method of any one of Aspects 56-68, wherein the glass comprises a pore size of 1 nm to 50 nm.

Aspect 70 provides the method of any one of Aspects 56-69, wherein the glass comprises a pore size of 2 nm to 20 nm.

Aspect 71 provides the method of any one of Aspects 56-70, wherein the glass comprises porous borosilicate glass.

Aspect 72 provides the method of any one of Aspects 56-71, wherein the glass comprises an alkali-borosilicate glass that has been phase separated and has had the resulting alkali- and boric acid-rich phase dissolved in acid without subsequent melting to consolidate pores thereof.

Aspect 73 provides the method of Aspect 72, wherein the glass comprises about 96 wt % silica and about 4 wt % boron trioxide.

Aspect 74 provides the method of any one of Aspects 56-73, wherein the porous glass is borosilicate glass formed using a phase separation temperature of 560° C. to 600° C.

Aspect 75 provides the method of any one of Aspects 56-74, wherein the glass is borosilicate glass formed using an acid-leaching time of 3 days to 30 days.

Aspect 76 provides the method of any one of Aspects 56-75, further comprising HF-modifying the glass prior to the treatment with the solution comprising the quantum dots.

Aspect 77 provides the method of Aspect 76, wherein the HF-modification comprises modification of the internal surface of the glass with HF having a concentration of 0.01 wt % to 10 wt % in water.

Aspect 78 provides the method of any one of Aspects 76-77, wherein the HF-modification comprises modification of the internal surface of the glass with HF having a concentration of 0.1 wt % to 1 wt % in water.

Aspect 79 provides the method of any one of Aspects 76-78, wherein the HF-modification comprises modification of the internal surface of the glass with HF for a duration of 1 h to 200 h.

Aspect 80 provides the method of any one of Aspects 76-79, wherein the HF-modification comprises modification of the internal structure of the glass with HF for a duration of 12 h to 36 h.

Aspect 81 provides the method of any one of Aspects 76-80, further comprising annealing the glass after the HF-modification.

Aspect 82 provides the method of Aspect 81, wherein the annealing comprises annealing in air.

Aspect 83 provides the method of any one of Aspects 81-82, wherein the annealing comprises annealing at 300° C. to 800° C. for 1 min to 8 h,

Aspect 84 provides the method of any one of Aspects 81-83, wherein the annealing comprises annealing at 550° C. to 650° C. for 30 min to 2 h.

Aspect 85 provides the method of any one of Aspects 56-84, further comprising modifying the glass prior to the treatment with the solution, the modifying comprising modifying the glass with a Si—OH-reducing material that reduces surface Si—OH concentration of the glass.

Aspect 86 provides the method of Aspect 85, wherein the Si—OH-reducing material comprises Cl₂, F₂, NH₃, or a combination thereof.

Aspect 87 provides the method of any one of Aspects 56-86, further comprising modifying the quantum dots prior to the treatment of the glass with the solution, the modifying comprising modifying the quantum dots with a surface-modifying material that reduces surface defects in the quantum dot, changes surface chemistry of the quantum dot, and/or increases quantum yield of the quantum dots doped in the glass.

Aspect 88 provides the method of Aspect 87, wherein the surface-modifying material comprises I₂, Br₂, Cl₂, an alkyl-carboxylate acid, an alkyl amine, an alkyl thiol, a metal alkyl-carboxylate complex, or a combination thereof,

Aspect 89 provides the method of any one of Aspects 56-88, wherein the quantum dots comprise more than one type of quantum dot.

Aspect 90 provides the method of any one of Aspects 56-89, wherein the quantum dots have a diameter of 1 nm to 50 nm.

Aspect 91 provides the method of any one of Aspects 56-90, wherein the quantum dots have a diameter of 2 nim to 20 nm.

Aspect 92 provides the method of any one of Aspects 56-91, wherein the quantum dots comprise ZnO, ZnS, ZnSe, ZnTe, CdS, CdSe, CdTe, HgTe, HgSe, HgS, InAs, InP, InSb, Si, C, Ge, PbS, PbSe, PbTe, CuInS₂, CsPbCl₂, CsPbBr₃, CsPbI₃, alloys thereof, core/shell structures of any combination thereof, or combinations thereof.

Aspect 93 provides the method of any one of Aspects 56-92, wherein the quantum dots comprise core/shell quantum dots, wherein the core and the shell independently comprise ZnO, ZnS, ZnSe, Znie, CdS, CdSe, CdTe, HgTe, HgSe, HgS, InAs, InP, InSb, Si, C, Ge, PbS, PbSe, PbTe, CuIn₂, CsPbCl₃, CsPbBr₃, CsPbI₃, alloys thereof, or combinations thereof.

Aspect 94 provides the method of any one of Aspects 56-93, wherein the quantum dots comprise CdSe.

Aspect 95 provides the method of any one of Aspects 56-94, wherein the quantum dots comprise ZnS.

Aspect 96 provides the method of any one of Aspects 56-95, wherein the quantum dots comprise CdSe/ZnS core/shell quantum dots.

Aspect 97 provides the method of any one of Aspects 56-96, further comprising sealing the quantum dots within the glass.

Aspect 98 provides the method of any one of Aspects 56-97, further comprising sealing the quantum dots within the glass via one or more layers of optically transparent material.

Aspect 99 provides the method of Aspect 98, wherein the one or more layers independently comprise a thickness of 1 nm to 1500 nm.

Aspect 100 provides the method of any one of Aspects 98-99, wherein the one or more layers independently comprise a thickness of 5 nm to 1000 nm.

Aspect 101 provides the method of any one of Aspects 98-100, comprising using atomic layer deposition to deposit the one or more layers comprising a layer comprising Al₂O₃, SiO₂, Si₃N₄, or a combination thereof.

Aspect 102 provides the method of Aspect 101, wherein the layer comprising Al₂O₃, SiO₂, Si₃N₄, or a combination thereof, has a thickness of 5-10 nm.

Aspect 103 provides the method of any one of Aspects 98-102, wherein the one or more layers comprises a PVD- or PECVD- deposited layer having a thickness of 100 nm to 1000 nm.

Aspect 104 provides the method of any one of Aspects 98-103, wherein sealing the quantum dots within the glass comprises using atomic layer deposition to deposit the one or more layers comprising a layer adjacent to the glass comprising Al₂O₃, SiO₂, Si₃N₄, or a combination thereof, that has a thickness of 5-10 nm, and performing PVD- or PECVD-deposition to deposit a layer thereon having a thickness of 100 nm to 1000 nm.

Aspect 105 provides the quantum dot-doped glass or method of making the same of any one or any combination of Aspects 1-104 optionally configured such that all elements or options recited are available to use or select from.

What is claimed is:

1. A quantum dot-doped glass comprising:
glass comprising quantum dots in pores in the glass, wherein the quantum dots are sealed within the glass via one or more layers of optically transparent material, wherein the quantum dots within the glass have a photoluminescence quantum yield of ≥10%.

2. The quantum dot-doped glass of claim 1, wherein the quantum dots have a photoluminescence quantum yield of ≥40%.

3. The quantum dot-doped glass of claim 1, wherein the quantum dots are 0.0001 wt % to 5 wt % of the quantum dot-doped glass, and wherein the quantum dots have a diameter of 1 nm to 50 nm.

4. The quantum dot-doped glass of claim 1, wherein the pores comprising the quantum dots are in a surface layer of the glass, the surface layer having a thickness of 1 micron to 2000 microns, and the pores having a pore size of 1 nm to 50 nm.

5. The quantum dot-doped glass of claim 1, wherein the glass comprises porous borosilicate glass.

6. The quantum dot-doped glass of claim 1, wherein the glass is HF-modified.

7. The quantum dot-doped glass of claim 1, wherein
the glass is a modified glass that has reduced surface Si—OH concentration,
the quantum dot is a surface-modified quantum dot having reduced surface defects, altered surface chemistry, and/or having increased quantum yield when doped in the glass, or
a combination thereof.

8. The quantum dot-doped glass of claim 1, wherein the quantum dots comprise ZnO, ZnS, ZnSe, ZnTe, CdS, CdSe, CdTe, HgTe, HgSe, HgS, InAs, InP, InSb, Si, C, Ge, PbS, PbSe, PbTe, CuInS₂, CsPbCl₃, CsPhBr₃, CsPbI₃, alloys thereof, core/shell structures of any combination thereof, or combinations thereof.

9. The quantum dot-doped glass of claim 1, wherein the quantum dots comprise CdSe/ZnS core/shell quantum dots.

10. The quantum dot-doped glass of claim 1, the one or more layers of optically transparent material comprise
a layer comprising Al₂O₃, SiO₂, Si₃N₄, or a combination thereof,
a PVD- or PECVD-deposited layer having a thickness of 100 nm to 1000 nm, or
a combination thereof.

11. A quantum dot-doped glass comprising:
porous borosilicate glass comprising quantum dots dispersed in pores in a surface layer of the glass, the pores having a pore size of 2 nm to 20 nm;
wherein
the quantum dots are sealed within the glass via one or more layers of optically transparent material comprising
a layer composing Al₂O₃, SiO₂, Si₃N₄, or a combination thereof,
a PVD- or PECVD-deposited layer having a thickness of 100 nm to 1000 nm, or
a combination thereof;
the surface layer has a thickness of 5 microns to 1000 microns; and
the quantum dots within the glass have a photoluminescence quantum yield of ≥10%.

12. A method of forming a quantum dot-doped glass, the method comprising:
treating a glass with a solution comprising quantum dots to place the quantum dots into pores in the glass;
sealing the quantum dots within the glass via one or more layers of optically transparent material to form the quantum dot-doped glass, wherein the quantum dots within the glass have a photoluminescence quantum yield of ≥10%.

13. The method of claim 12, wherein the treating comprises soaking the glass in the solution for a duration of 1 h to 1 week, wherein the solution comprises an organic solvent.

14. The method of claim 12, wherein the glass comprises porous borosilicate glass.

15. The method of claim 12, further comprising HF-modifying the glass prior to the treatment with the solution comprising the quantum dots.

16. The method of claim 15, further comprising annealing the glass after the HF-modification.

17. The method of claim 12, further comprising
modifying the glass prior to the treatment with the solution, the modifying comprising modifying the glass with a Si—OH-reducing material that reduces surface Si—OH concentration of the glass,
modifying the quantum dots prior to the treatment of the glass with the solution, the modifying comprising modifying the quantum dots with a surface-modifying material that reduces surface defects in the quantum dot, changes surface chemistry of the quantum dot, and/or increases quantum yield of the quantum dots doped in the glass, or
a combination thereof.

18. The method of claim 12, wherein the quantum dots have a diameter of 1 nm to 50 nm.

19. The method of claim 12, wherein the quantum dots comprise CdSe/ZnS core/shell quantum dots.

20. The method of claim 12, wherein the sealing comprises
using atomic layer deposition to deposit the one or more layers comprising a layer comprising Al₂O₃, SiO₂, Si₃N₄, or a combination thereof,
using PVD- or PECVD-deposition to deposit the one or more layers comprising a PVd- or PECVD-deposited layer haying a thickness of 100 nm to 1000 nm, or
a combination thereof.
